(19) United States
(12) Patent Application Publication
(10) Pub. No.: US 2020/0003828 A1
(43) Pub. Date: Jan. 2, 2020

(54) LABELING SYSTEM AND METHOD FOR DEFECT CLASSIFICATION

(71) Applicant: UTECHZONE CO., LTD., New Taipei City (TW)

(72) Inventors: ARULMURUGAN AMBIKAPATHI, New Taipei City (TW); Chien-Chung Lin, New Taipei City (TW); Cheng-Hua Hsieh, New Taipei City (TW)

(73) Assignee: UTECHZONE CO., LTD., New Taipei City (TW)

(21) Appl. No.: 16/455,771

(22) Filed: Jun. 28, 2019

(30) Foreign Application Priority Data
Jun. 29, 2018 (TW) 107122643

(51) Int. Cl. G01R 31/28; G06K 9/62; G06T 7/00

(52) U.S. Cl. CPC G01R 31/2836; G06T 7/001; G06K 9/626; G06K 9/6256

(57) ABSTRACT

A labeling system for defect classification having a storage unit and a processing unit is provided. The storage unit stores a defect classification module, a defect labeling module, and a catalog generation module. The processing unit performs the modules aforementioned. The defect classification module is configured to provide a defect type information. The defect labeling module marks a defect type label to at least one test object image according to an image feature and the defect type information on the at least one test object image. The catalog generation module receives the labeled test object images and moves test object images having the same defect type label to a corresponding file catalog.

### CROSS-REFERENCE TO RELATED APPLICATION

This application claims the priority benefit of Taiwan application serial no. 107122643, filed on Jun. 29, 2018. The entirety of the above-mentioned patent application is hereby incorporated by reference herein and made a part of this specification.

### BACKGROUND OF THE INVENTION

### Field of the Invention

The invention relates to a classification technique, and more particularly, to a labeling system and method for defect classification.

### Description of Related Art

With the advancement of technology, the precision requirements of electronic components are increasing. To ensure an increase in the yield of electronic components, an optical inspection stage and a re-inspection stage are included in the manufacture of a circuit board. The optical inspection stage involves obtaining a test object image and determining if a defect is present in the test object. The re-inspection stage involves further verifying the label for the determined defect in the optical detection stage via a manual method.

In the current industrial process, a deep-learning method has gradually been adopted to develop artificial intelligence, so as to reduce the manpower-consuming of the re-inspection stage. However, the training of deep-learning is based on a large number of samples. In other words, a large amount of data needs to be first manually labeled and then inputted into a deep-learning model to improve the training level of the module. During the process, a large number of images causes a manpower-consuming as well. In addition, if the operator is inexperienced, then the duration of manual labeling is extended. Moreover, since there are many types of defects, the operator often feels overwhelmed when classifying defects. Accordingly, how to improve the process of defect classification to reduce manual labor is an important topic for those skilled in the art.

### SUMMARY OF THE INVENTION

The invention provides a labeling system and method for defect classification to provide an intuitive and smooth classification labeling process.

The labeling system for defect classification of the invention has a storage unit and a processing unit. The storage unit stores a defect classification module, a defect labeling module, and a catalog generation module. The processing unit performs the modules aforementioned. The defect classification module is configured to provide a defect type information. The defect labeling module marks a defect type label to at least one test object image according to an image feature and the defect type information of the at least one test object image. The catalog generation module receives the labeled test object images and moves test object images having the same defect type label to a corresponding file catalog.

The labeling method for defect classification of the invention has the following steps. A defect type information is provided. At least one test object image is marked with a defect type label according to an image feature and the defect type information of the at least one test object image. The labeled test object images are received and test object images having the same defect type label are moved to a corresponding file catalog.

Based on the above, via the defect classification module, the defect labeling module, and the catalog generation module, the labeling system and method for defect classification of the invention provide a smoother and intuitive classification process to reduce manual labor.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The markings illustrate exemplary embodiments of the disclosure and, together with the description, serve to explain the principles of the disclosure.

FIG. 1 shows a schematic of a labeling system for defect classification of an embodiment of the invention.

FIG. 2 shows a schematic of a labeling system for defect classification of another embodiment of the invention.

FIG. 3 shows a side view of a labeling system for defect classification corresponding to the embodiment of FIG. 2.

FIG. 4 shows a flowchart of a labeling method for defect classification of an embodiment of the invention.

FIG. 5 shows a flowchart of the operation of a labeling system for defect classification of an embodiment of the invention.

### DESCRIPTION OF THE EMBODIMENTS

During manual labeling, an operator usually classifies a defect image to a corresponding folder according to the defect type of the defect image. To reduce the tedious operation process for the operator, the invention provides a labeling system and method for defect classification.

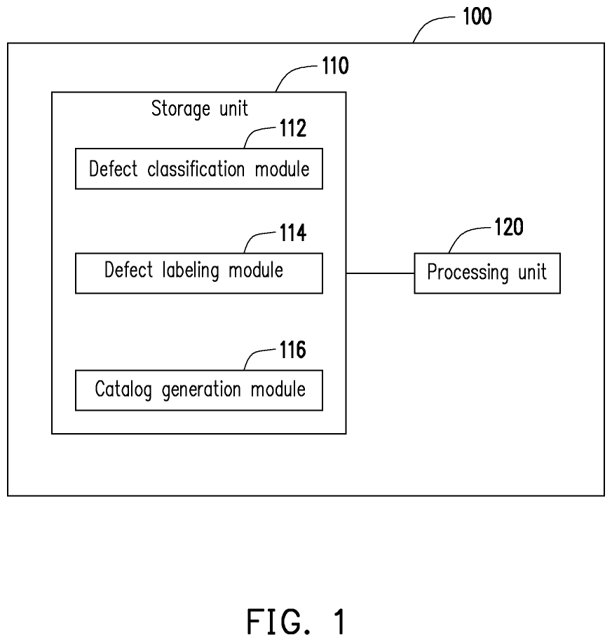

FIG. 1 shows a schematic of a labeling system for defect classification of an embodiment of the invention.

A labeling system 100 for defect classification has a storage unit 110 and a processing unit 120.

The storage unit 110 is configured to store software, data, and various codes needed for the operation of the labeling system 100 for defect classification. In particular, the storage unit 110 stores a defect classification module 112, a defect labeling module 114, and a catalog generation module 116.

The defect classification module 112 provides a defect type information. The defect type information is, for instance, inner and outer layer offset, terminal discoloration, foreign body on terminal, exposed copper on terminal, unclear text, ink falling off, gold surface discoloration, foreign body on gold surface, exposed copper on gold surface, electrical measurement, finger injury by crushing, solder mask falling off, gold surface damage by crushing, or FPC filth, but the invention is not limited thereto.

The defect labeling module 114 is configured to mark a test object image with a defect type label according to an image feature and defect type information on the test object image.

The catalog generation module 116 receives the labeled test object images and moves test object images having the same defect type label to a corresponding file catalog.

In an embodiment of the invention, the storage unit 110 is, but not limited to, for instance, any form of a fixed or movable random-access memory (RAM), read-only memory (ROM), flash memory, hard disk drive (HDD), solid-state drive (SSD), or similar devices or a combination of the above devices.

The processing unit 120 is connected to the storage unit 110 and configured to perform various operations of the labeling system 100 for defect classification. In particular, the processing unit 120 performs the defect classification module 112, the defect labeling module 114, and the catalog generation module 116 to run the labeling method for defect classification. The processing unit 120 can be a central processing unit (CPU) or a general-purpose or special-purpose programmable microprocessor, digital signal processor (DSP), programmable controller, application-specific integrated circuit (ASIC), or other similar devices or a combination of the above devices, but the invention is not limited thereto.

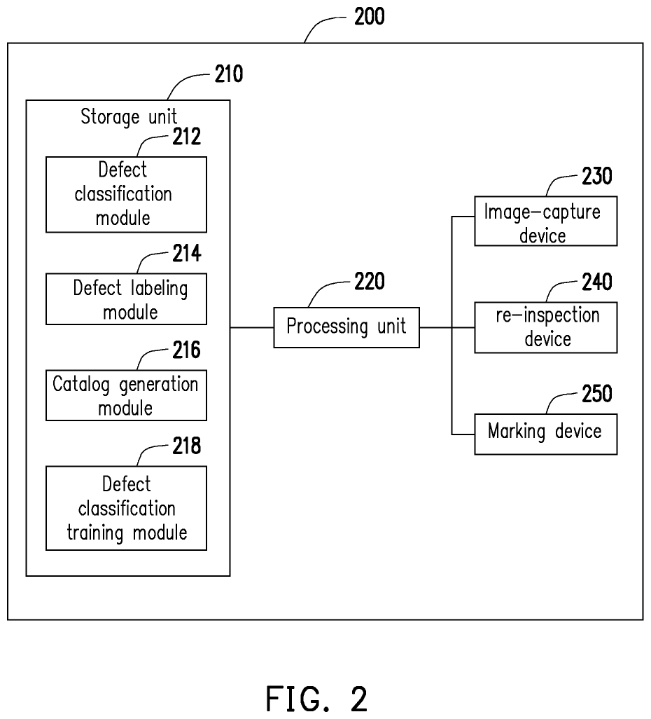

FIG. 2 shows a schematic of a labeling system for defect classification of another embodiment of the invention. A labeling system 200 for defect classification of the present embodiment not only has a storage unit 210 and a processing unit 220, but also has an image-capture device 230, a re-inspection device 240, and a marking device 250.

The storage unit 210 and the defect classification module 212, the defect labeling module 214, and the catalog generation module 216 stored by the storage unit 210 are the same as the storage unit 110 and the defect classification module 112, the defect labeling module 114, and the catalog generation module 116 stored by the storage unit 110 and the processing unit 120 of FIG. 1 and are therefore not repeated herein.

Moreover, the storage unit 210 also stores a defect classification training module 218 to train a corresponding classification model according to a file catalog. The defect classification training module 218 trains a classification model corresponding to each defect by using a deep-learning model on an image. In the invention, the deep-learning model is, for instance, a LeNet model, an AlexNet model, a GoogleNet model, or a VGG model (Visual Geometry Group), but the invention is not limited thereto. In other embodiments of the invention, the defect classification training module 218 can also be operated using other independent devices.

The processing unit 220 is the same as the processing unit 120 of FIG. 1 and is therefore not repeated herein.

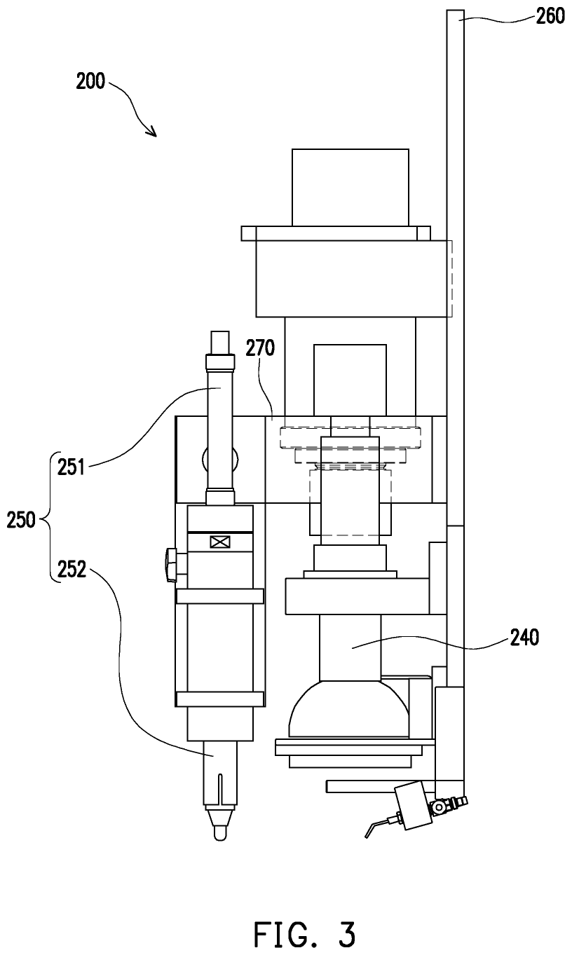

In the invention, the image-capture device 230, the re-inspection device 240, and the labeling device 250 of the labeling system 200 for defect classification are electrically connected to the processing unit 220. To facilitate the understanding of the components of the labeling system 200 for defect classification of the present embodiment, please refer to both FIG. 2 and FIG. 3. FIG. 3 shows a side view of a labeling system for defect classification corresponding to the embodiment of FIG. 2.

In the invention, the image-capture device 230, the re-inspection device 240, and the labeling device 250 of the labeling system 200 for defect classification are integrated into one body. The image-capture device 230 can be a line scan camera and an area scan camera configured to obtain an image of a test object 20.

The re-inspection device 240 is integrated at one side of the image-capture device 230, wherein the re-inspection device 240 can be a microscope configured to assist the operator to obtain a magnified image of the test object 20 to perform the step of verifying the test object 20.

Moreover, the labeling device 250 is integrated at one side of the re-inspection device 240, wherein the labeling device 250 can be a marking pen configured to label a defective block on the test object 20.

In the present embodiment, the optical detection equipment 100 further includes a carrier 260 and a bracket 270 connected to the carrier 260, wherein the image-capture device 230 and the re-inspection device 240 are fixed on the carrier 260, and the image-capture device 230 and the re-inspection device 240 are disposed in parallel. The bracket 270 is extended between the image-capture device 230 and the recheck device 240 from the side on the carrier 260 where the image-capture device 230 and the recheck device 240 are located, and the labeling device 250 parallel to the recheck device 240 is fixed on the bracket 270. Specifically, the bracket 270 has a first end portion and a second end portion opposite to the first end portion, wherein the first end portion is connected to the carrier 260, the second end portion exceeds between the image-capture device 230 and the recheck device 240, and the labeling device 250 is fixed on the second end portion.

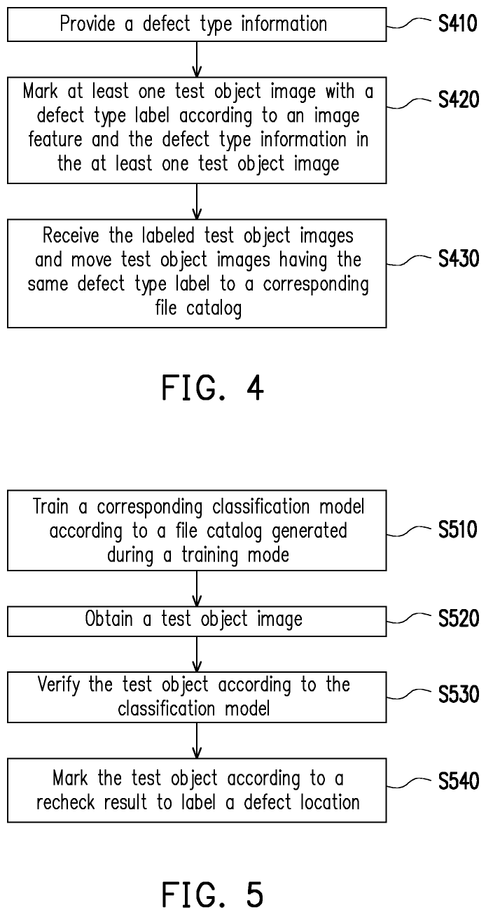

FIG. 4 shows a flowchart of a labeling method for defect classification of an embodiment of the invention. It should be mentioned that, the labeling method for defect classification of the embodiment of FIG. 4 is suitable for the labeling system 100 for defect classification shown in FIG. 1, and is also suitable for the labeling system 200 for defect classification shown in FIG.2 and FIG. 3. To avoid confusion, in the following, the reference numerals in the labeling system 200 for defect classification of FIG. 2 and FIG. 3 are used, but the invention is not limited thereto.

In the invention, the processing unit 220 runs the defect classification module 212, the defect labeling module 214, and the catalog generation module 216 to run the labeling method for defect classification.

In step S410, the defect classification module 212 provides a defect type information.

In step S420, the defect labeling module 214 marks a defect type label to at least one test object image according to an image feature and the defect type information of the at least one test object image.

In step S430, the catalog generation module 216 receives the labeled test object images and moves test object images having the same defect type label to a corresponding file catalog. In the invention, each file catalog corresponds to one defect type label.

To more clearly describe the operation process of the labeling method for defect classification, in the following, the labeling method for defect classification is described in three different operational scenarios. However, in the actual operation of the invention, the operating environment is different according to, for instance, different product types, industry policies, and user needs. Without departing from the spirit of the invention, different designs are all within the scope of the invention.

[First Operational Scenario]

In the first operational scenario, the labeling system 200 for defect classification is operated on the basis of classification type of the defect to generate a defect type label.

Specifically, the processing unit 220 shows a user interface on a screen at the same time to provide a classification type input field. The operator can input a specified classification type in the classification type input field via various types of input units (such as a mouse, keyboard, or touch screen), such as selecting one classification type by inputting a classification code or classification name, or by ticking corresponding checkbox. The processing unit 220 generates a defect label signal according to the input operation of the operator. The defect classification module 212 provides a defect type information according to the defect classification signal (step S410).

The processing unit 220 also reads a test object image and shows the test object image on the screen. The operator selects one or a plurality of test object images for which the defect feature belongs to the inputted classification type. The processing unit 220 generates an image selection signal according to the input operation of the operator. The defect labeling module 214 marks a defect type label to the selected test object images according to an image feature and the defect type information of the selected test object images (step S420).

The labeled test object images are sent to the catalog generation module 216. The catalog generation module 216 receives the labeled test object images and moves test object images having the same defect type label to a corresponding file catalog (step S430).

It should be mentioned that, in the first operational scenario, the operator can select one or a plurality of test object images and mark the test object images with the same defect type label. Therefore, via the labeling system 200 for defect classification of the invention, the operator only needs to input the classification type at the beginning to classify a plurality of test object images of such type, and does not need to perform repeated operations on different test object images.

[Second Operational Scenario]

In the second operational scenario, the labeling system 200 for defect classification is operated on the basis of a test object image to generate a defect type label.

Specifically, the processing unit 220 reads a test object image and shows the test object image on the screen. The operator selects one or a plurality of test object images to be classified. The processing unit 220 generates an image selection signal according to the input operation of the operator.

The processing unit 220 shows a user interface on the screen at the same time to provide a classification type input field. The operator can input a specified classification type in the classification type input field via various types of input units (such as a mouse, keyboard, or touch screen). Different from the first operational scenario, the classification type input field shows various different classification types for the operator to select. The processing unit 220 generates a defect label signal according to the input operation of the operator. The defect classification module 212 provides a defect type information according to the defect classification signal (step S410).

The defect labeling module 214 marks a defect type label to the selected test object images according to an image feature and the defect type information on the selected test object images (step S420).

The labeled test object images are sent to the catalog generation module 216. The catalog generation module 216 receives the labeled test object images and moves test object images having the same defect type label to a corresponding file catalog (step S430).

[Third Operational Scenario]

In the third operational scenario, the defect classification module 212 provides a defect type information according to a preset classification algorithm (step S410). The invention does not limit the type of the classification algorithm, and the classification algorithm can be designed and adjusted according to practical needs.

The defect classification module 212 marks a defect type label to the selected test object images according to an image feature and defect type information of the selected test object images (step S420).

The labeled test object images are sent to the catalog generation module 216. The catalog generation module 216 receives the labeled test object images and moves test object images having the same defect type label to a corresponding file catalog (step S430).

In other words, in the third operational scenario, all of the classification and labeling are completed by the labeling system 200 for defect classification.

FIG. 5 shows a flowchart of the operation of a labeling system for defect classification of an embodiment of the invention.

In step S510, during the training mode, the classification training module 218 trains a classification model according to the corresponding file catalog. Since each of the file catalogs corresponds to one defect type, the classification training module 218 generates classification models corresponding to different defect classifications using the file catalog as a training unit.

In step S520, the image-capture device 230 obtains a test object image. In an embodiment of the invention, the labeling system 200 for defect classification is connected to an automatic optical detection equipment and receives a defect list from the automatic optical detection equipment. The automatic optical detection equipment captures a test object image and generates a defect list according to the defect determination result of the test object image. The labeling system 200 for defect classification further obtains an image according to the defect location recorded in the defect list.

In step S530, the re-inspection device 240 verifies the test object according to the classification model. By reading the classification model generated by the classification training module 218, the re-inspection device 240 determines the classification of the defect of the test object image to reduce the burden of the operator.

In step S540, the marking device 250 marks the test object according to the recheck result to label the defect location.

Based on the above, via the defect classification module, the defect labeling module, and the catalog generation module, the labeling system and method for defect classification of the invention provide a smoother and intuitive classification labeling process to reduce manual labor.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A labeling system for a defect classification, comprising:
a storage unit, storing a plurality of modules; and
a processing unit, performing the modules, the modules includes:
a defect classification module, configured to provide a defect type information;
a defect labeling module, marking a defect type label to at least one test object image according to an image feature and the defect type information of the at least one test object image; and
a catalog generation module, receiving the labeled test object images and moving test object images having a same defect type label to a corresponding file catalog.

2. The labeling system for the defect classification of claim 1,
wherein the defect classification module further receives a defect labeling signal corresponding to the at least one test object image and provides the defect type information according to the defect labeling signal.

3. The labeling system for the defect classification of claim 1, further comprising:
a defect classification training module, training a corresponding classification model according to the file catalog.

4. The labeling system for the defect classification of claim 1, further comprising:
an image-capture device, configured to obtain the test object images;
a verifying device, integrated to a side of the image-capture device and configured to verify the test object according to a classification model; and
a marking device, integrated to a side of the recheck device and configured to mark the test object.

5. A labeling method for a defect classification, comprising:
providing a defect type information;
marking a defect type label on at least one test object image according to an image feature and the defect type information of the at least one test object image; and
receiving the labeled test object images and moving test object images having a same defect type label to a corresponding file catalog.

6. The labeling method for the defect classification of claim 5, comprising, in the step of providing the defect type information:
receiving a defect labeling signal corresponding to the at least one test object image and providing the defect type information according to the defect labeling signal.

7. The labeling method for the defect classification of claim 5, further comprising:
training a corresponding classification model according to the file catalog.

8. The labeling method for the defect classification of claim 5, further comprising:
obtaining the test object images;
verifying the test object according to a classification model, wherein the classification model is generated according to the file catalog; and
marking the test object according to a recheck result.
